(19) United States
(12) Patent Application Publication
(10) Pub. No.: US 2018/0190872 A1
(43) Pub. Date: Jul. 5, 2018

(54) ELECTRODE AND PHOTOELECTRIC SEMICONDUCTOR DEVICE USING THE SAME

(71) Applicant: Lextar Electronics Corporation, Hsinchu (TW)

(72) Inventor: Shiu-Li HUANG, Kaohsiung City (TW)

(21) Appl. No.: 15/840,077

(22) Filed: Dec. 13, 2017

(30) Foreign Application Priority Data
Dec. 30, 2016 (TW) 105144218

(51) Int. Cl. H01L 33/40; H01L 33/38

(52) U.S. Cl. CPC H01L 33/405; H01L 33/62; H01L 33/38

(57) ABSTRACT

An electrode and a photoelectric semiconductor device using the same are provided. The electrode includes a pad layer, a barrier layer and a reflection layer, which are formed in order. The barrier layer is formed between the reflection layer and the pad layer.

This application claims the benefit of Taiwan application Serial No. 105144218, filed Dec. 30, 2016, the subject matter of which is incorporated herein by reference.

### BACKGROUND OF THE INVENTION

### Field of the Invention

The invention relates in general to an electrode and a photoelectric semiconductor device using the same, and more particularly to an electrode having a reflection layer and a photoelectric semiconductor device using the same.

### Description of the Related Art

When a conventional photoelectric semiconductor device is excited, a light is emitted through the combination of electrons and holes. However, the excited light may not be fully emitted off the photoelectric semiconductor device, and a part of the light will be reflected within the photoelectric semiconductor device. The light reflected within the photoelectric semiconductor device could be absorbed by some layer structures within the photoelectric semiconductor device and cause the intensity and extraction efficiency of the light emitted by the photoelectric semiconductor device to decrease. Therefore, it has become a prominent task for the industry to provide a new technology to resolve the above problems.

### SUMMARY OF THE INVENTION

The present invention is directed to an electrode and a photoelectric semiconductor device using the same capable of resolving the problem encountered in the prior art.

According to one embodiment of the present invention, an electrode is provided. The electrode includes a pad layer, a barrier layer and a reflection layer, which are formed in order. The barrier layer is formed between the reflection layer and the pad layer.

According to another embodiment of the present invention, a photoelectric semiconductor device is provided. The photoelectric semiconductor device includes a photoelectric semiconductor structure and an electrode. The electrode is formed on the photoelectric semiconductor structure, wherein the pad layer, the barrier layer and the reflection layer are formed in order and disposed in a direction away from the photoelectric semiconductor structure.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 is a schematic diagram of a photoelectric semiconductor device according to an embodiment of the present invention.

FIG. 2 is a reflectivity curve of the second reflection layer of FIG. 1.

### DETAILED DESCRIPTION OF THE INVENTION

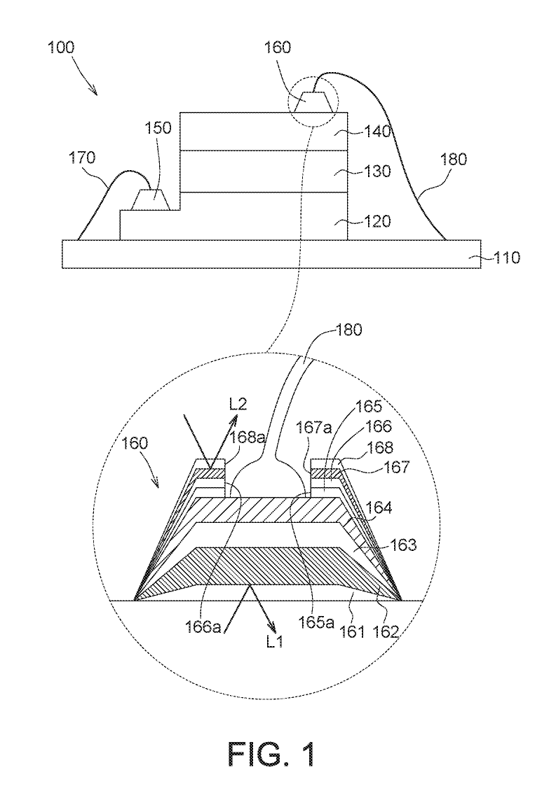

Referring to FIG. 1, a schematic diagram of a photoelectric semiconductor device 100 according to an embodiment of the present invention is shown. The photoelectric semiconductor device 100 includes a substrate 110, a photoelectric semiconductor structure, a first type semiconductor layer 120, a light emitting layer 130, a second type semiconductor layer 140, a first electrode 150, a second electrode 160, a first solder 170 and a second solder 180. The photoelectric semiconductor structure includes a first type semiconductor layer 120, a light emitting layer 130 and a second type semiconductor layer 140.

The first type semiconductor layer 120, the light emitting layer 130 and the second type semiconductor layer 140 are formed on the substrate 110 in order. The light emitting layer 130 is formed between the first type semiconductor layer 120 and the second type semiconductor layer 140. The light emitting layer 130 emits a light after being excited. The first type semiconductor layer 120 is an N-type semiconductor layer, and the second type semiconductor layer 140 is a P-type semiconductor layer. Or, the first type semiconductor layer 120 is a P-type semiconductor layer, and the second type semiconductor layer 140 is an N-type semiconductor layer. In terms of materials, the P-type semiconductor layer can be realized by a gallium nitride semiconductor layer doped with beryllium (Be), zinc (Zn), manganese (Mn), chromium (Cr), magnesium (Mg), calcium (Ca); the N-type semiconductor layer can be realized by a gallium nitride semiconductor layer doped with silicon (Si), germanium (Ge), tin (Sn), sulfur (S), oxygen (O), titanium (Ti) and or zirconium (Zr); the light emitting layer 130 can be realized by a an InxAlyGa1-x-yN (0≤x, 0≤y, x+y≤1) structure or a single-layered or multi-layered structure doped with boron (B) or phosphorus (P) or arsenic (As).

The first electrode 150 and the second electrode 160 are respectively formed on the first type semiconductor layer 120 and the second type semiconductor layer 140 to electrically connect the first type semiconductor layer 120 and the second type semiconductor layer 140. Besides, the first solder 170 connects the first electrode 150 and the substrate 110, and the second solder 180 connects the second electrode 160 and the substrate 110, such that an external current can drive the light emitting layer 130 through the first solder 170, the second solder 180, the first electrode 150 and the second electrode 160 to emit a light. As indicated in FIG. 1, the light emitting layer 130 can emit the lights L1 and L2 irradiated towards the first electrode 150 through different optical paths.

The structure of the first electrode 150 is identical or similar to that of the second electrode 160. In embodiments of the present invention, the second electrode 160 is used for exemplary and explanatory purpose. The second electrode 160 includes a first contact layer 161, a first reflection layer 162, a first barrier layer 163, a pad layer 164, a second contact layer 165, a second barrier layer 166, a second reflection layer 167 and a protection layer 168 formed on the second type semiconductor layer 140 in order and disposed in a direction away from the photoelectric semiconductor structure.

The first reflection layer 162 can reflect the light L1 coming from underneath off the photoelectric semiconductor device 100 through other optical path, such that the intensity and extraction efficiency of the light can be enhanced. The first contact layer 161 is disposed between the first reflection layer 162 and the second type semiconductor layer 140, such that the associativity between the first reflection layer 162 and the second type semiconductor layer 140 can be enhanced through the disposition of the first contact layer 161. In other words, if the associativity between the first reflection layer 162 and the second type semiconductor layer 140 is poor, the first contact layer 161 can be used to increase the stability between the first reflection layer 162 and the second type semiconductor layer 140. In terms of material, in an embodiment, the first contact layer 161 contains titanium (Ti), nickel (Ni), chromium (Cr), rhodium (Rh) or a combination thereof, and the first reflection layer 162 contains aluminum (Al), copper (Cu), silver (Au), rhodium (Rh) or a combination thereof.

The first barrier layer 163 is disposed between the first reflection layer 162 and the pad layer 164 and prevents the pad layer 164 from generating chemical reaction with the first reflection layer 162. Under a high-temperature process or environment, the elements of the first reflection layer 162 and the elements of the pad layer 164 may be diffused due to high temperature and generate chemical reaction with each other. However, due to the obstruction of the first barrier layer 163, the possible chemical reaction can be reduced or even be avoided. In an embodiment, the first barrier layer 163 can be a stacked structure formed of a single-layered metal, an alloy or a multi-layer metal, wherein the single-layered metal is such as chromium (Cr), titanium (Ti), tungsten (W), nickel (Ni), and platinum (Pt); the alloy is such as tungsten titanium alloy and nickel-chromium alloy; the multi-layer metal is such as Ti/Pt/Ti/Pt, Ti/Ni/Ti/Ni, Ti/Ni-Cr/Ti/Ni—Cr.

The pad layer 164 connects the first solder 170 and provides excellent conductivity to reduce impedance and increase the electrical quality of current transmission. In an embodiment, the pad layer 164 contains gold (Au) or an alloy thereof. The material of the first solder 170 and the pad layer 164 can be formed of similar materials such that the associativity between the pad layer 164 and the first solder 170 can be enhanced. The second solder 180 the first solder 170 can be formed of similar materials, and the similarities are not repeated here.

The second reflection layer 167 can reflect the light L2 coming from above off the photoelectric semiconductor device 100 through other optical path, such that the intensity and extraction efficiency of the light can be enhanced. When the reflectivity of the pad layer 164 is too low or is below expectation, the second reflection layer 167 can be used to reflect the light L2. Thus, the design of the pad layer 164 (such as material) is not affected by reflectivity, and the design of the second reflection layer 167 can compensate the inadequacy of the pad layer 164. Furthermore, the second reflection layer 167 can be a metal layer formed of aluminum, silver or other metal. Preferably, the second reflection layer 167 has a reflectivity higher than 80%, and can effectively reflect the light L2. In another embodiment, the second reflection layer 167 can be realized by a distributed Bragg reflector (DBR) or an omni-directional reflector (ODR).

As indicated in FIG. 1, the second reflection layer 167 covers the lateral sides and a part of the upper surface of the second barrier layer 166, and can reflect the light L2 irradiated on the sides and the top of the second reflection layer 167. Of the second contact layer 165, the second barrier layer 166 and the second reflection layer 167, the second reflection layer 167 is the topmost layer and is closest to the light L2, and therefore can reflect the light L2. Since the light L2 is directly reflected by the second reflection layer 167 without having to pass through the second barrier layer 166 and the second reflection layer 167, the light loss is reduced.

The second contact layer 165 is disposed between the second barrier layer 166 and the pad layer 164, such that the associativity between the second barrier layer 166 and the pad layer 164 can be enhanced through the disposition of the second contact layer 165. In other words, if the second barrier layer 166 is an oxide layer, the associativity between the second barrier layer 166 and the pad layer 164 is normally poor. However, when the second barrier layer 166 and the pad layer 164 are connected through the second contact layer 165, the associativity between the second barrier layer 166 and the pad layer 164 will be enhanced. In an embodiment, the oxide layer is such as a silicon dioxide layer. Besides, the second contact layer 165 and the first contact layer 161 can be formed of similar materials, and the similarities are not repeated here; the second barrier layer 166 and the first barrier layer 163 can be formed of similar materials, and the similarities are not repeated here. In another embodiment, depending on the material of the second barrier layer 166 and the material of the pad layer 164, if the associativity between the second barrier layer 166 and the pad layer 164 can meet the requirement, the second contact layer 165 can be omitted.

The second barrier layer 166 is disposed between the second reflection layer 167 and the second contact layer 165 and prevents the second reflection layer 167 from generating chemical reaction with the second contact layer 165. Under a high-temperature process or environment, the elements of the second reflection layer 167 and the elements of the second contact layer 165 may be diffused due to high temperature and generate chemical reaction with each other. However, due to the obstruction of the second barrier layer 166, the possible chemical reaction can be reduced or even be avoided. In an embodiment, the second barrier layer 166 and the first barrier layer 163 can be formed of similar materials, and the similarities are not repeated here.

the protection layer 168 is formed on the second reflection layer 167 and covers the second reflection layer 167 to avoid the second reflection layer 167 being damaged due to oxidation and moisturization caused by the external environment. In an embodiment, the protection layer 168 contains an insulation material such as silicon dioxide or aluminum oxide. In another embodiment, the protection layer 168 can be omitted, such that the light L2 can directly enter the second reflection layer 167 without passing through the protection layer 168, and the light loss can thus be reduced.

As indicated in FIG. 1, the second barrier layer 166, the second reflection layer 167, the second contact layer 165 and the protection layer 168 have a first opening 166a, a second opening 167a, a third opening 165a and a fourth opening 168a, respectively. The first opening 166a, the second opening 167a, the third opening 165a and the fourth opening 168a expose the pad layer 164, such that the first solder 170 can contact the pad layer 164 through the openings.

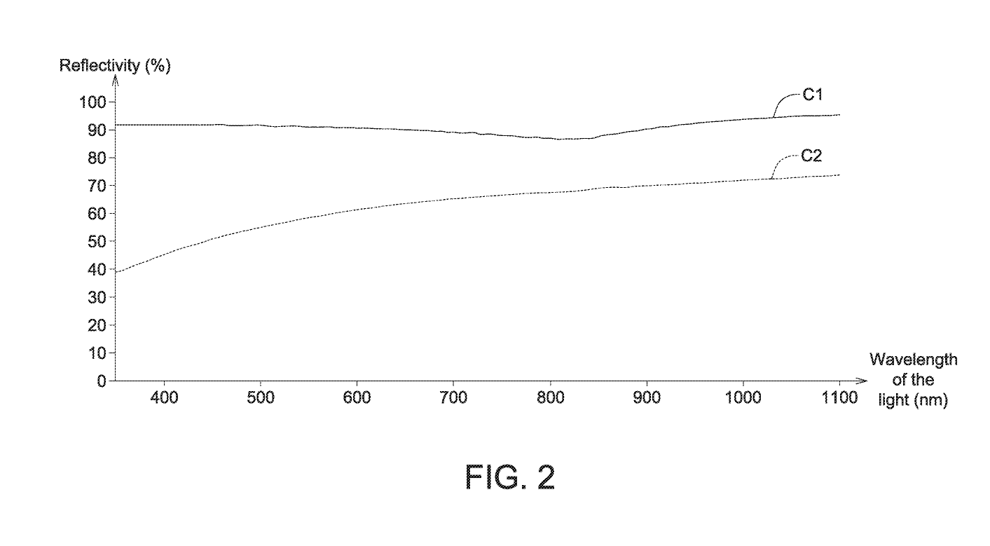

FIG. 2 is a reflectivity curve of the second reflection layer 167 of FIG. 1. The curve C1 represents the reflectivity of the second reflection layer 167 measured under different wavelengths of the light. The curve C2 represents the reflectivity of other reflection layer measured under different wavelengths of the light. The curve C1 represents the reflectivity of aluminum, and the curve C2 represents the reflectivity of nickel. It can be seen from the diagram that, the reflectivity of aluminum is over 80% and is higher than the reflectivity of nickel measured under all wavelengths of the light. The second reflection layer 167 of the embodiments of the present invention has a reflectivity higher than 80%, and therefore effectively reflects the light.

While the invention has been described by way of example and in terms of the preferred embodiment (s), it is to be understood that the present disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electrode, comprising:
a pad layer, a barrier layer and a reflection layer which are formed in order;
wherein the barrier layer is formed between the reflection layer and the pad layer, and the barrier layer and the reflection layer respectively have a first opening and a second opening, and the first opening and the second opening expose the pad layer.

2. The electrode according to claim 1, wherein the barrier layer is made of a material comprising an oxide layer, titanium, tungsten titanium, nickel-chromium alloy or tungsten.

3. The electrode according to claim 1, wherein the electrode further comprises:
a contact layer formed between the barrier layer and the pad layer.

4. The electrode according to claim 3, wherein the contact layer contains titanium, nickel or chromium.

5. The electrode according to claim 1, wherein the reflection layer is made of a material comprising aluminum, aluminum-copper alloy, silver, silver alloy, a distributed Bragg reflector (DBR) or an omni-directional reflector (ODR).

6. The electrode according to claim 1, wherein the reflection layer has a reflectivity higher than 80%.

7. The electrode according to claim 1, wherein the electrode further comprises:
a protection layer formed on the reflection layer.

8. The electrode according to claim 7, wherein the protection layer contains silicon dioxide or aluminum oxide.

9. The electrode according to claim 1, wherein the barrier layer contains a single-layered metal or a multi-layered metal, the single-layered metal contains chromium, titanium, tungsten, nickel or platinum, and the multi-layer metal is a stacked structure formed of Ti/Pt/T/Pt, a stacked structure formed of Ti/Ni/Ti/Ni or a stacked structure formed of Ti/Ni Cr/Ti/Ni chromium.

10. A photoelectric semiconductor device, comprising:
a photoelectric semiconductor structure; and
an electrode according to claim 1 formed on the photoelectric semiconductor structure, wherein the pad layer, the barrier layer and the reflection layer are formed in order and disposed in a direction away from the photoelectric semiconductor structure.

11. The photoelectric semiconductor device according to claim 10, wherein the barrier layer is made of a material comprising an oxide layer, titanium, tungsten titanium, nickel-chromium alloy or tungsten.

12. The photoelectric semiconductor device according to claim 10, wherein the electrode further comprises:
a contact layer formed between the barrier layer and the pad layer.

13. The photoelectric semiconductor device according to claim 12, wherein the contact layer contains titanium, nickel or chromium.

14. The photoelectric semiconductor device according to claim 10, wherein the reflection layer is made of a material comprising aluminum, aluminum-copper alloy, silver, silver alloy, a DBR or an ODR.

15. The photoelectric semiconductor device according to claim 10, wherein the reflection layer has a reflectivity higher than 80%.

16. The photoelectric semiconductor device according to claim 10, wherein the electrode further comprises:
a protection layer formed on the reflection layer.

17. The photoelectric semiconductor device according to claim 16, wherein the protection layer contains silicon dioxide or aluminum oxide.

18. The photoelectric semiconductor device according to claim 10, wherein the barrier layer contains a single-layered metal or a multi-layered metal, the single-layered metal contains chromium, titanium, tungsten, nickel or platinum, and the multi-layer metal is a stacked structure formed of Ti/Pt/Ti/Pt, a stacked structure formed of Ti/Ni/Ti/Ni or a stacked structure formed of Ti/Ni Cr/Ti/Ni chromium.
